(19) United States
(12) Patent Application Publication
(10) Pub. No.: US 2024/0105872 A1
(43) Pub. Date: Mar. 28, 2024

(54) INTERCONNECTOR FOR SOLAR CELL STRINGS INTENDED TO FORM A PHOTOVOLTAIC MODULE

(71) Applicant: COMMISSARIAT A L'ENERGIE ATOMIQUE ET AUX ENERGIES ALTERNATIVES, Paris (FR)

(72) Inventors: Yannick ROUJOL, Grenoble Cedex 09 (FR); Julien GAUME, Grenoble Cedex 09 (FR); Clément JAMIN, Grenoble Cedex 09 (FR); Baptiste PERON, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/257,439

(22) PCT Filed: Dec. 16, 2021
(86) PCT No.: PCT/EP2021/086088

§ 371 Date: Jun. 14, 2023

(30) Foreign Application Priority Data
Dec. 16, 2020 (FR) 2013393

(51) Int. Cl. H01L 31/05; H01L 31/048; H01L 31/18

(52) U.S. Cl. CPC H01L 31/0508; H01L 31/0488; H01L 31/0512; H01L 31/1876

(57) ABSTRACT

An interconnector for solar cell strings intended to form a photovoltaic module, the interconnector comprising at least one cell interconnecting strip extending beyond a cell located at the end of the string through an end, and at least one string interconnecting strip, a section of one from among the cell interconnecting strip and the string interconnecting strip has a substantially constant surface, and a variable shape between a first zone of a first thickness and a second zone of a second thickness, the second thickness being strictly less than the first thickness and the second thickness being strictly less than 50 μm. Each second zone thus constitutes a resistance welding zone without loss in terms of conduction. Without extra thickness at the interconnections, the risk of the module breaking is limited.

### TECHNICAL FIELD OF THE INVENTION

The present invention relates to the field of photovoltaic modules, in particular intended for a space application. The present invention relates more specifically to the problem of interconnectors and assemblies between solar cell strings to form a photovoltaic module. It has a particularly advantageous application in the field of interconnections and assemblies between solar cell strings, and in particular, between solar cell strings forming a photovoltaic module intended for a space application.

### STATE OF THE ART

The interconnection principle makes it possible to establish an electric connection between two individual solar cells or between several strings of a photovoltaic module by way of a conductive material, called interconnector.

The designs and techniques of interconnection between two individual solar cells are generally different between land applications and space applications.

For land applications, the standard of interconnection between two individual solar cells consists of the use of copper and tin-plated, soldered or bonded interconnecting strips, on the solar cells. The standard thickness of each of these interconnecting strips is around 200 μm for a width varying from a few hundred microns to a few millimetres. The corresponding section is compatible with the operating currents of silicon-based solar cells, generally implemented for land applications. These currents are standardly between 6 and 12 A.

For space applications, the standard of interconnection between two individual solar cells consists of the use of molybdenum, Invar (FeNi) or Kovar (FeNiCo), silver- or gold-plated interconnectors, which are resistance welded. These interconnectors have a specific geometry making it possible to resist high thermal amplitudes of the space environment. The standard thickness of these interconnectors is around 25 μm for a width going up to several millimetres. This section is compatible with the operating to currents of multi-junction space cells, which are standardly less than 1 A.

If the use of silicon-based solar cells in a space environment is quite rare, the Hubble telescope is an example of this. It implements silicon cells, of which the 2 cm×4 cm surface area enables the use of a silver-plated molybdenum interconnector, comprising a so-called “out-of-plane” relaxation loop, to electrically connect two individual solar cells together. It is therefore possible to use, for space applications, silicon-based solar cells interconnected two-by-two by interconnectors developed for space applications.

Moreover, the assembly together of solar cell strings makes it possible to electrically connect solar cell strings of one same module, even or several modules, together. This assembly standardly comprises an interconnection between:
at least one interconnecting strip, such as those making it possible to interconnect two adjacent cells of a string together (by extending, for example, over a first of the two cells to under the other of the two adjacent cells together for a series connection of these cells), an end of said at least one interconnecting strip extending at the end of the string; such a strip will subsequently be called, “cell interconnecting strip”, and
at least one strip for interconnecting between strings and/or between several cell interconnecting strip ends at the end of the string, and this will subsequently be called, “string interconnecting strip”.

Whether for space or land applications, this assembly has risks of panels breaking, in particular during their manufacture. In particular, for so-called glass-to-glass configurations, wherein the assembly is encapsulated before being sandwiched between two glass plates, extra thicknesses at the assemblies between cell interconnecting strip and string interconnecting strip can lead to the breaking of glass plates, in particular during their transfer. Such extra thicknesses are particularly observable, as cell interconnecting strip(s) and string interconnecting strip(s) are interconnected by soldering or bonding, which both involve an addition of material.

An aim of the present invention is to propose an assembly between cell interconnecting strip(s) and string interconnecting strip(s) which makes it possible to overcome at least one of the disadvantages of the state of the art.

An aim of the present invention is more specifically to propose an assembly between cell interconnecting strip(s) and string interconnecting strip(s), which makes it possible to limit, even remove, the risk of panels breaking, in particular during their production.

Another aim of the invention is to propose a solution for integrating silicon-based solar cell panels adapted to both space and land applications.

Other aims, features and advantages of the present invention will appear upon examining the following description and the accompanying drawings. It is understood that other advantages can be incorporated.

### SUMMARY OF THE INVENTION

To achieve at least one of these aims, an interconnector for at least one solar cell string intended to form at least one part of a photovoltaic module is provided, according to a first aspect of the invention.

The interconnector comprises at least one cell interconnecting strip extending partially over one cell of the string, the cell being located at the end of the string. Each cell interconnecting strip extends beyond said cell, over which it extends by an end.

The interconnector further comprises at least one string interconnecting strip. Each string interconnecting strip can be arranged to interconnect at least two cell interconnecting strip ends and/or at least two cell strings together.

Each from among said at least one cell interconnecting strip and said at least one string interconnecting strip extends in a main direction over a thickness measured in a direction perpendicular to a plane, wherein the solar cell string mainly extends.

A section in a plane perpendicular to said main direction of an element taken from among said at least one cell interconnecting strip and said at least one string interconnecting strip has:
a substantially constant surface, and
a variable shape along at least the main direction between a first thickness zone Z1 and a second thickness zone Z2, the thickness Z2 of the second zone being strictly less than the thickness Z1 of the first zone and the thickness Z2 of the second zone being strictly less than 50 μm.

Thus, each second zone can constitute an electrically conductive welding zone, and in particular a resistance welding zone.

To ensure a compatibility between the resistance welding method and the principle of interconnection by cell interconnecting strip(s) and string interconnecting strip(s), it is provided to modify the section of the cell interconnecting strip(s) and/or the string interconnecting strip(s) zones, which are intended to be welded in order to reduce the thickness of the interconnection. More specifically, the welding zones can have been punched to locally decrease the thickness of the interconnecting means, while preserving the section of these means in order to not lose electric performance.

An interconnector enabling the electric connection of solar cell strings together, while by being adapted to a resistance welding method, is therefore in particular proposed.

Thanks to this interconnector, there is no longer extra thickness at the interconnections between cell interconnecting strip(s) and string interconnecting strip(s). Thus, the risk of panels breaking, in particular during their production, is limited, even removed.

Furthermore, the interconnector according to the first aspect of the invention, makes it possible produce photovoltaic modules, in particular with silicon-based solar cells, which resist the thermal stresses of the space environment. In particular, the absence of soldering or bonding due to the option of using the resistance welding technique, makes it possible to limit the number of different materials involved in the interconnection and therefore is less subject to the differences in coefficients of thermal expansion between materials involved.

A second aspect relates to a photovoltaic module comprising solar cells, preferably silicon-based, and at least one interconnector such as introduced above.

A third aspect relates to a method for assembling a photovoltaic module according to the second aspect of the invention. The assembly method comprises a step of resistance welding between said at least one cell interconnecting strip and said at least one string interconnecting strip at at least one second zone.

### BRIEF DESCRIPTION OF THE FIGURES

The aims, objectives, as well as the features and advantages of the invention will best emerge from the detailed description of an embodiment of the latter, which is illustrated by the following accompanying drawings, wherein:

FIG. 1 schematically represents a top view of a photovoltaic panel according to a first known architecture.

FIG. 2A schematically represents a top view of a photovoltaic panel according to a second known architecture.

FIG. 2B represents an enlargement of the zone referenced A in FIG. 2A.

FIG. 3A schematically represents a top view of a first embodiment of the invention.

FIG. 3B schematically represents a partial cross-sectional view of the first embodiment of the invention along the cutting plane referenced A-A in FIG. 3A.

FIG. 4 schematically represents a partial cross-sectional view of a second embodiment of the invention.

FIG. 5 schematically represents a partial cross-sectional view of a third embodiment of the invention.

FIG. 6A schematically represents a partial cross-sectional view of a photovoltaic module 1 according to the prior art.

FIG. 6B schematically represents a partial cross-sectional view of a photovoltaic module 1 according to an embodiment of the invention.

FIGS. 7A and 7B each illustrate a step of the method for stamping the end of a cell interconnecting strip of an interconnector according to an embodiment of the invention.

The drawings are given as examples and are not limiting of the invention. They constitute principle schematic representations intended to facilitate the understanding of the invention, and are not necessarily to the scale of practical applications. In particular, the relative thicknesses of the different elements represented, as well as their relative proportions in directions perpendicular to their thickness, are not necessarily representative of reality.

### DETAILED DESCRIPTION OF THE INVENTION

Before starting a detailed review of embodiments of the invention, below, optional features are stated, which can optionally be used in association or alternatively:

According to an example, with said element being a cell interconnecting strip, it comprises a second zone located at the end through which it extends beyond the cell located at the end of the string.

According to an example, with said element being a string interconnecting strip, it comprises a second zone by cell interconnecting strip without a second zone, even by cell interconnecting strip, each second zone of the string interconnecting strip preferably being distant from at least one other second zone of the string interconnecting strip by a distance substantially equal to a separation distance between cell interconnecting strips adjacent to one another, the latter being arranged substantially parallel to one another.

According to an example, the interconnector comprises at least two cell interconnecting strips, and at least one, preferably each, of the ends of said at least two cell interconnecting strips is interconnected at the other of the two ends by said at least one string interconnecting strip by being resistance welded to it at at least one second zone.

According to an example, the interconnector comprises at least two cell interconnecting strips, and at least one, preferably each, of the ends of said at least two cell interconnecting strips is interconnected to the other of the two ends by a string interconnecting strip by being resistance welded to it at two second zones superposed to one another, one belonging to one of said at least two cell interconnecting strips, the other to the string interconnecting strip.

According to an example, the first zone has a thickness greater than or equal to 70 μm, preferably greater than 100 μm, and even more preferably, substantially equal to 200 μm, the thickness being measured perpendicularly to a plane wherein the solar cell string mainly extends.

According to an example, the thickness Z1 is the maximum thickness that the element has over the whole of its extent along the main direction.

According to an example, the part of each interconnecting strip which extends over the cell located at the end of the string is without a second zone. Thus, it is avoided to opacify the cell and to proportionally reduce its yield.

According to an example, the width of each interconnecting strip at each first zone is less than or substantially equal to 1 mm.

According to an example, each second zone extends over:
a substantially flat surface entering into the plane wherein the solar cell string mainly extends, and/or
a surface area substantially equal to 1 mm² projecting over the plane wherein the solar cell string mainly extends.

According to an example, said element comprises a relaxation loop.

According to an example, said element is copper-based, and comprises, if necessary, a surface tin-plating of a thickness substantially between 20 and 25 μm and/or a pure Ag, SnAg, SnPbAg or SnBiAg composition.

According to an example, the interconnector is more specifically an interconnector for at least one silicon-based solar cell string.

According to an example, the interconnector has no soldering or bonding.

According to an example, in the photovoltaic module according to the second aspect of the invention:
said at least one interconnector makes an electric junction between at least two solar cell strings, according to a series or parallel configuration of said at least two strings, and/or
said at least one interconnector is intended to make an electric junction between at least one solar cell string and external electronics.

According to an example, the photovoltaic module according to the second to aspect of the invention comprises two protective plates and an encapsulant, said at least one interconnector and said at least one solar cell string being encapsulated by the encapsulant sandwiched between the two protective plates, the latter being, if necessary, constituted of a glass base.

According to an example, the assembly method according to the third aspect of the invention further comprises a step of stamping, in a mould comprising an imprint and a punch, a cell interconnecting strip of constant section and of thickness equal to said thickness Z1. The imprint and the punch are preferably configured to deform the end of the cell interconnecting strip by stressing it to progressively be spread out transversally to its thickness, so as to preserve the unchanged length of the cell interconnecting strip, while progressively reducing its thickness until reaching said thickness Z2 and form a second zone.

By solar cell “string”, this means a substantially linear succession of solar cells in a plane, the cells being connected together by at least one interconnecting strip between each pair of successive cells in the alignment. Ordinarily, each interconnecting strip joins the two cells of each pair together, by extending under a first of the two cells, then on the second of the two cells, a space between the cells being provided at which the interconnecting strip changes sides relative to the plane wherein the cells enter.

It is specified that in the scope of the present invention, the term “thickness” means, unless mentioned otherwise, a dimension of the object in question, which is perpendicular to a plane, wherein a solar cell string, or a photovoltaic module comprising this string, mainly extends.

The term “width” itself means the dimension of a longitudinal object, such as a strip, which is perpendicular to the longitudinal extension direction of the object and parallel to the plane wherein the photovoltaic module mainly extends.

The “section” of a longitudinal object, such as a strip is defined by the shape, the surface and the dimensions of a transverse flat cross-section of this object.

By a parameter “substantially equal to/greater than/less than” a given value, this means that this parameter is equal to/greater than/less than the given value, plus or minus 10%, even 5%, of this value. By a parameter “substantially between” two given values, this means that this parameter is, as a minimum, equal to the lowest given value, plus or minus 10%, even 5%, of this value, and as a maximum, equal to the greatest given value, plus or minus 10%, even 5%, of this value.

When the term “substantially” refers to the quality of an object, for example when it relates to an object of substantially constant section, i.e. that this quality, as a minimum, accommodates certain measuring errors, or that this quality is to be assessed regarding the function of the object, and/or an acceptable possible degradation of this function, regarding it all, such as a photovoltaic module, wherein the object enters. Thus, the section of each of the interconnecting strips that it relates to in this case, is preferably constant, to close measuring errors, but can also slightly vary, beyond said measuring errors, if its function which is to conduct, for example according to certain specification, the electric current produced by the solar cells is not altered to the point that the photovoltaic module comprising the interconnecting strips would not be more operational or would lose any interest due to a yield which is too low.

Initially, the invention aimed to enable a wider use of photovoltaic panels composed of photovoltaic modules, the solar cells of which are silicon-based for space applications.

With this in mind, several problems were to be considered.

First, the impossibility of welding interconnecting strips together with the resistance welding method has been noted as soon as the thickness of the elements to be welded was around 200 microns, as is the case of elements widely used to interconnect silicon-based solar cell strings together for land applications. Indeed, resistance welding such thicknesses of materials requires to provide a significant energy input, not compatible with current equipment and/or leading to significant deformations and aesthetic defects.

Moreover, electric performance losses through resistive losses have been noted in case of using interconnectors specific to space applications to interconnect silicon-based solar cell strings together. Indeed, as mentioned in the introduction, the currents that can support these interconnectors are weaker, around an order of magnitude, with respect to those that silicon-based solar cell string interconnectors must be able to support.

Furthermore, the interconnecting strips used for land applications often being copper-based have a coefficient of thermal expansion (around 17 ppm for copper) greater than those of materials such as molybdenum (the coefficient of thermal expansion of which is around 4.8 ppm), Inver® (the coefficient of thermal expansion of which is around 1.6 ppm) and Kovar® (the coefficient of thermal expansion of which is around 5.1 ppm) themselves used to constitute interconnectors specific to space applications. Copper-based interconnecting strips are therefore, in principle, worse candidates for constituting interconnectors specific to space applications.

Then, interconnectors for land applications, often copper-based as mentioned above, are usually assembled by soldering interconnecting strips together. Such soldering gives them a low resistance to the space environment, in particular due to temperatures prevailing there, and temperature differences which are observed there. Indeed, these temperatures are at the start of mainly strong mechanical urges, which can lead to the rupture of welding seals obtained by soldering, like by bonding.

To respond to these initial problems, an interconnector 10 has been proposed for at least one solar cell 200 string 20 intended to form a photovoltaic module 1 according to the present invention.

As will appear below, the interconnector 10 can make it possible to electrically interconnect two solar cell 200 strings 20 together and/or to electrically interconnect a solar cell 200 string 20 to external electronics.

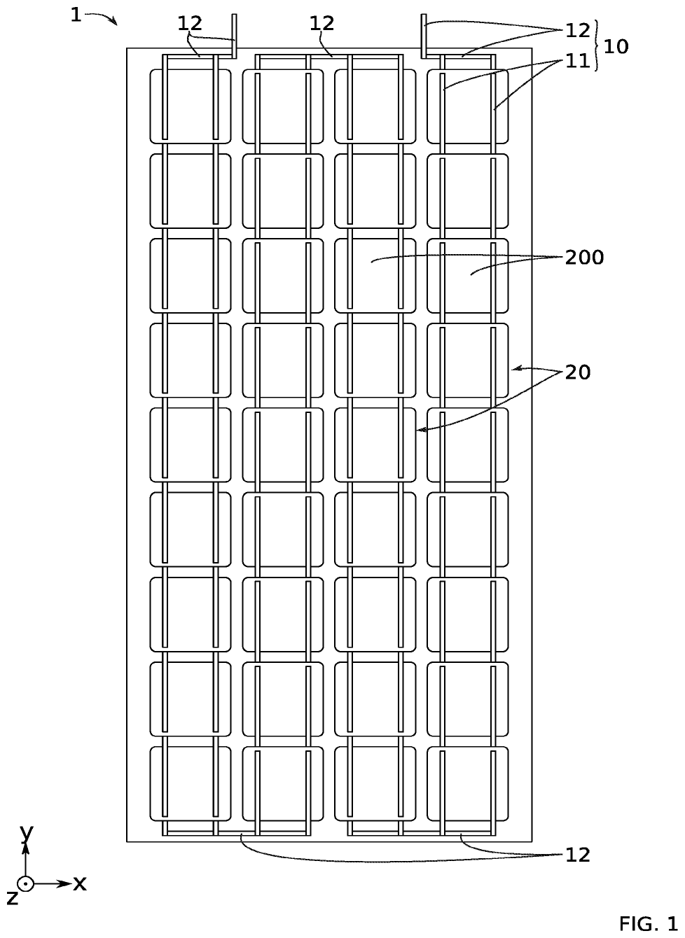

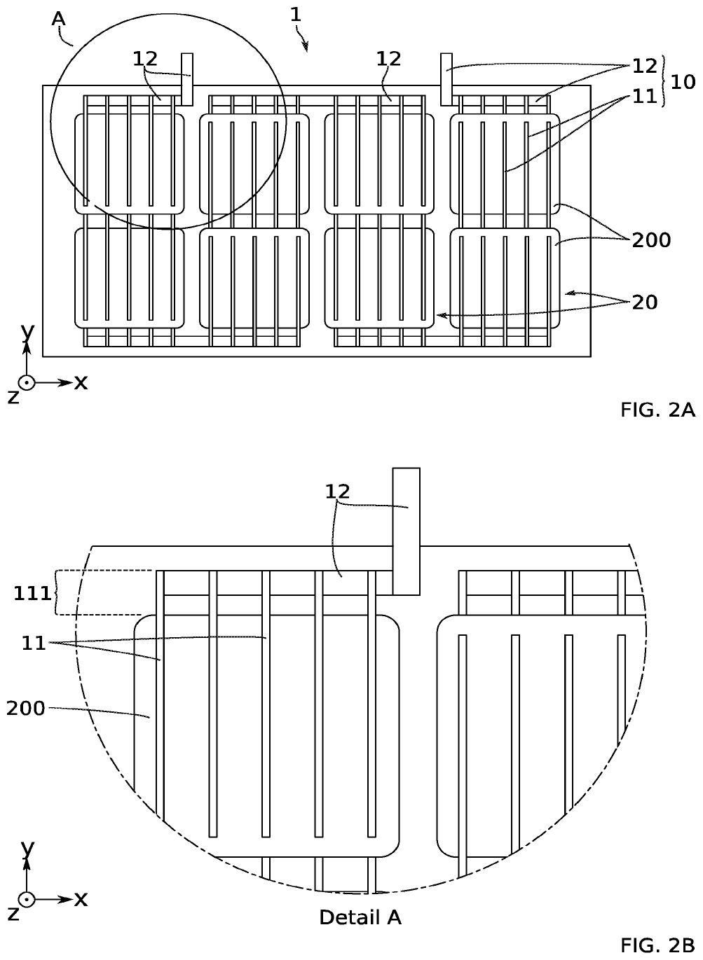

These two options are illustrated in FIGS. 1 and 2.

More specifically, FIG. 1 illustrates a series production of four solar cell 200 strings 20. At each end of this series of solar cells, an interconnector is located (represented respectively at the top, to the left and to the right, of FIG. 1) intended to enable a direct or indirect connection, to external electronics. Between these two interconnectors, an interconnector is located, electrically connecting the two strings 20 located at the centre of the photovoltaic module 1. At the bottom of FIG. 1, two other interconnectors are illustrated, connecting together, respectively, the two right-hand strings 20 and the two left-hand strings 20.

The architecture illustrated in FIG. 1 is an example of an architecture known from the prior art, on which the invention is advantageously applied.

FIG. 2A illustrates another example of this type of known architecture, on which the invention is intended to be applied.

Four strings of two solar cells are represented there. The cells having larger dimensions than those illustrated in FIG. 1, it is observed that more than two cell interconnecting strips 11, in this case, five cell interconnecting strips, extending at the end of each solar cell string. More specifically, each solar cell illustrated in FIG. 2A has a square shape, the side of which can be around equal to 15 cm. The number of electric connections to be ensured with each string interconnecting strip 12 being proportional to the number of cell interconnecting strips 11 extending over each solar cell 200 at the end of the string 20 and each interconnection being potentially a rupture zone, it emerges that the present invention will be even more advantageously applied to this second type of architecture illustrated, relative to the first type of architecture.

FIG. 2B is an enlargement over a zone referenced A illustrated in FIG. 2A. In to particular, it is only observed that it can be necessary to interconnect two string interconnecting strips 12 together, for example by two of their ends and perpendicularly to one another. The present invention first relates to the interconnexions between ends 111 of the cell interconnecting strips 11 at the end of the solar cell 200 string 20 and a string interconnecting strip 12, but also extends to possible interconnections between string interconnecting strips 12, in particular such as illustrated in FIG. 2B.

With this in mind, as mentioned above, and to achieve the objectives initially set, an interconnector 10 is proposed, comprising:
at least one cell interconnecting strip 11, five in FIG. 2A, extending over a cell 200 of the string 20, the cell 200 being located at the end of the string 20, and said at least one cell interconnecting strip 11 extending beyond said cell 200 through an end 111, and
at least one string interconnecting strip 12, each string interconnecting strip 12 being interconnected with the end 111 of each cell interconnecting strip 11, five of them in FIG. 2A.

Each interconnecting strip 11 and said at least one string interconnecting strip 12 extends in a main direction over a thickness measured in a direction perpendicular to a plane (x,y) wherein the solar cell 200 string 20 mainly extends.

The interconnector 10 is mainly such as a section in a plane perpendicular to said main direction, x or y, of an element 11, 12 taken from among said at least one cell interconnecting strip 11 and said at least one string interconnecting strip 12 has:
a substantially constant surface, and
a variable shape along the main direction at least between a first zone 101 of thickness Z1 and a second zone 102 of thickness Z2, the thickness Z2 of the second zone 102 being strictly less than the thickness Z1 of the first zone 101 and the thickness Z2 of the second zone 102 being strictly less than 50 μm.

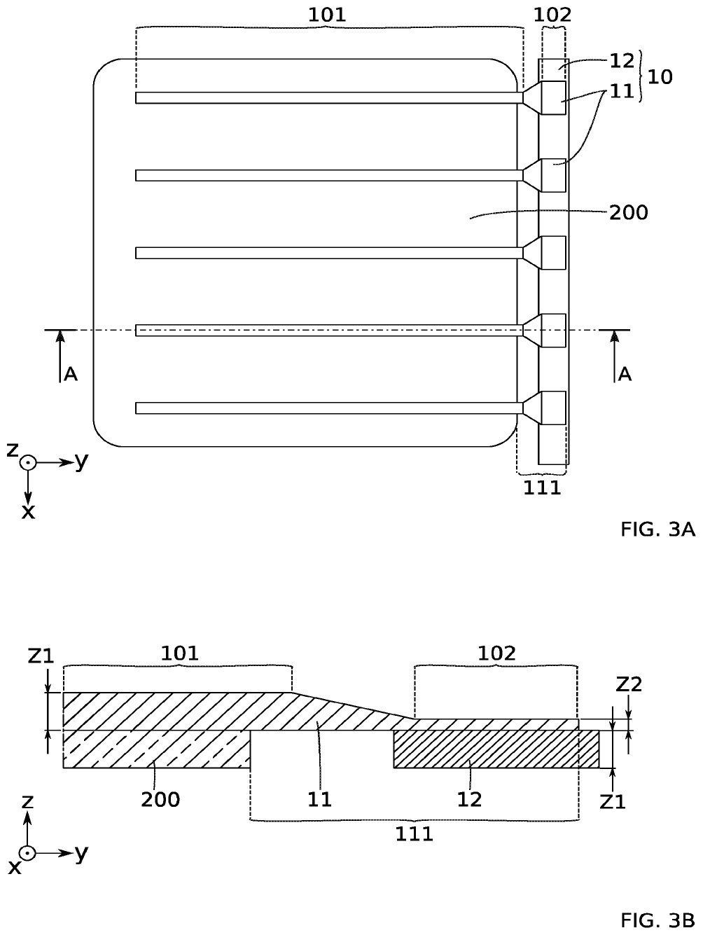

FIGS. 3A and 3B illustrate an embodiment, wherein each cell interconnecting strip 11 comprises a second zone 102 located at the end 111 through which it extends beyond the cell 200 located at the end of the string 20.

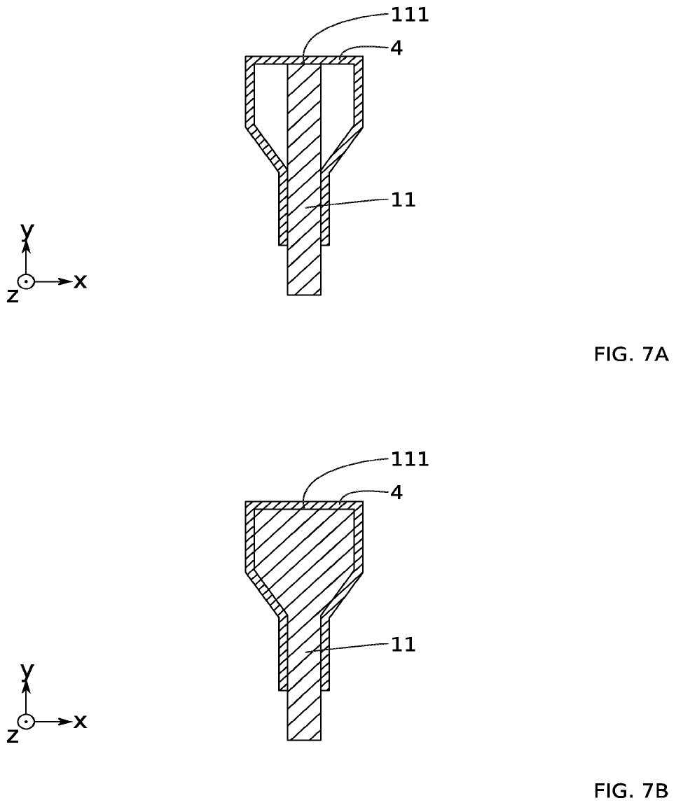

In this embodiment, the end 111 of each cell interconnecting strip 11 can have been moulded in the way illustrated by the top views that FIGS. 7A and 7B offer. More specifically, the end 111 of each cell interconnecting strip 11 can have been wedged against a wall of an imprint of a mould 4, before a punch of the mould 4 crushes the end 111 of the cell interconnecting strip 11 illustrated in FIG. 7A to deform it by to stressing it to progressively spread out transversally to its thickness so as to preserve the unchanged length of the cell interconnecting strip 11 while progressively reducing its thickness until reaching said thickness Z2 and form a second zone 102 in the way illustrated in FIG. 7B. In this way, the section of the cell interconnecting strip 11 is maintained constant over the whole of its length. Due to this, its electric performance is preserved.

Indeed, as FIGS. 3A and 3B illustrated together, the width in the direction x of the cell interconnecting strip 11 increases in the direction y at its end 111, while its height in the direction z decreases. The end 111 thus deformed preferably ends by a substantially flat surface entering into the plane (x,y), wherein the solar cell 200 string 20 mainly extends. Alternatively or complementarily, this surface is substantially equal to 1 mm² projecting over the plane (x,y).

In this way, the end 111 of said at least one cell interconnecting strip 11 according to the first embodiment of the invention has a surface by which it is possible, and particularly easy, to resistance weld it to said at least one string interconnecting strip 12. The interconnection thus obtained advantageously has no soldering or bonding, in particular in view of space applications.

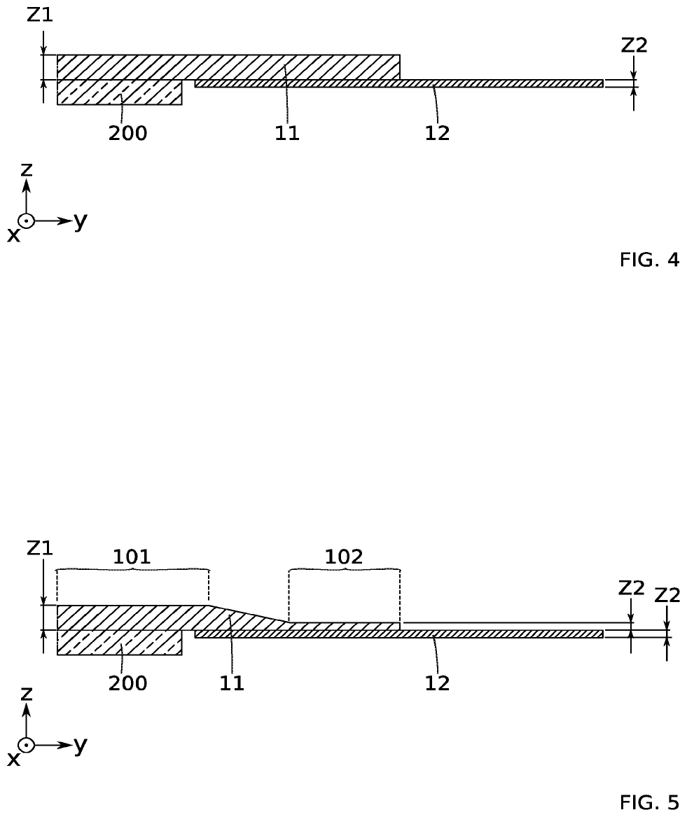

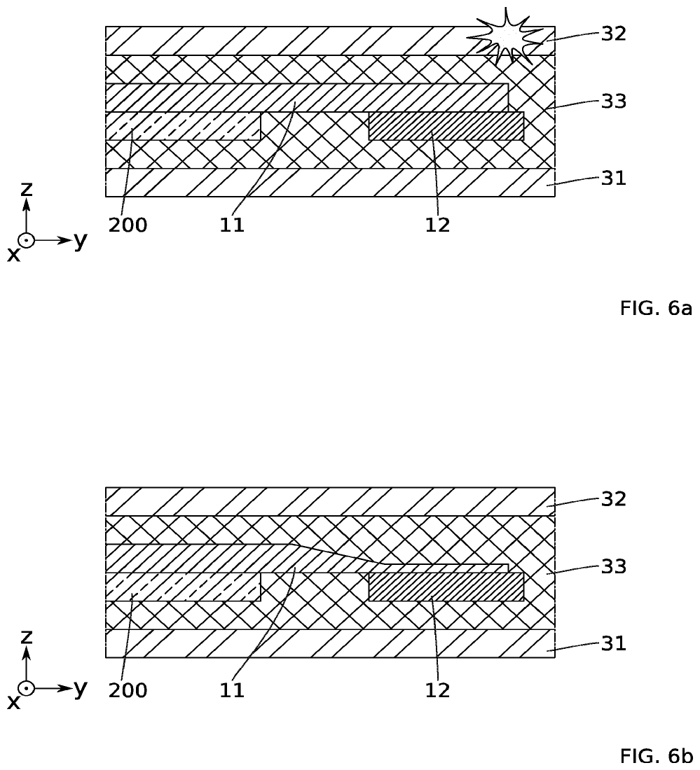

A second embodiment, having the same advantages, is illustrated in FIG. 4.

In this second embodiment, it is said at least one string interconnecting strip 12 which comprises a second zone 102; it comprises, more specifically one per cell interconnecting strip 11, each cell interconnecting strip 11 being without a second zone 102. It will be noted that, relative to the illustration offered by FIG. 3B, the section of the string interconnecting strip 12 illustrated in FIG. 4 is more extended in the direction y. This difference is explained by the preservation of the surface of the section in the plane (y,z) of the string interconnecting strip 12. Indeed, as described above in reference to the deformation of the end 111 of each interconnecting strip 11, a decrease in the height of the string interconnecting strip 12 is acquired at the expense of an increase in its width, along the axis y, such that the surface area of its section remains substantially constant, to preserve its electric performance. The second zones 102 of the string interconnecting strip 12 are preferably distant from one another by a distance equal to a separation distance between the interconnecting strips 11 themselves arranged substantially parallel to one another on the cell 200 located at the end of the string 20. Such string interconnecting strips 12 can easily be manufactured according to these specifications.

It will be noted that, in this embodiment, the resistance welding of the end 111 of to each cell interconnecting strip 11 with the string interconnecting strip 12 will be preferably done by the surface of the string interconnecting strip 12 of thickness Z2 located opposite said end 111.

A third embodiment is illustrated in FIG. 5.

In this third embodiment, each cell interconnecting strip 11 comprises a second zone 102 and the string interconnecting strip 12 comprises as many second zones 102 as it does cell interconnecting strips 11 to be interconnected together.

It will be noted that, in this third embodiment, the resistance welding of the end 111 of each cell interconnecting strip 11 with the string interconnecting strip 12 can be done by one or the other from among the surface of the string interconnecting strip 12 of thickness Z2 located opposite said end 111 of the surface of the end 111 of each cell interconnecting strip 11 of thickness Z2 located opposite the string interconnecting strip 12.

It is noted that, in each of the embodiments described above, the first zone 101 can have a thickness greater than or equal to 70 μm. It can even be greater than or equal to 100 μm, as is the case of interconnecting strips currently often used. It is further noted that, as illustrated in each of the figures, the thickness Z1 is preferably the maximum thickness that each interconnecting strip 11 and/or 12 has over the whole extent along its main extension direction. Moreover, the part of each cell interconnecting strip 11 which extends over the cell 200 located at the end of the string 20 is preferably without a second zone 102; in this way, overshadowing energy capturing surfaces of said solar cell 200 is avoided.

It is indeed preferable that the width of each cell interconnecting strip 11 at each first zone 101 is less than or substantially equal to 1 mm, so as to optimise the energy capturing surface of said solar cell 200. For this reason, it cannot be considered to make do with using interconnecting strips having a constant section of thickness Z2 and the surface area equal to that of a strip of thickness equal to 200 microns, as this would return to overshadowing the cells 200 too much, on which such interconnecting strips would extend. It is noted, that in this example, preserving the section of the interconnecting strip by passing from a thickness of 200 microns to a thickness of 50 microns, induces a quadrupling of the width of the strip.

The illustrations offered by FIGS. 7A and 7B are now considered.

The configuration illustrated in FIG. 7A relates to the prior art and the configuration illustrated in FIG. 7B relates to the present invention. They illustrate one same so-called glass-to-glass configuration of a photovoltaic module 1. In FIG. 7A, to the option that the photovoltaic module according to the prior art breaks due to the superposed thicknesses of the interconnecting strips 11 and 12 is illustrated, by the drawing of an impact. It must be noted that, in this illustration, the soldering or bonding material is not represented, which further increases the thickness of the interconnection such as represented. In comparison, it is noted, in FIG. 7B, that the thickness at the interconnection between each cell interconnecting strip 11 and the string interconnecting strip 12 is advantageously decreased, due to the implementation of the invention, as illustrated in this case by its first embodiment, but as this is verified for each of its embodiments.

It therefore emerges from the above that an advantage of the present invention is to limit, even remove, the risk of the photovoltaic module 1 breaking, in particular during its manufacture, but also during its use because of thermal stresses.

Thus, if the invention actually makes it possible, as initially targeted, to extend the use of silicon-based solar cells more widely to space applications, it also appears that the invention has an interest in terms of making photovoltaic modules 1 viable, whether this is:
for space or land applications, and/or
for silicon-based solar cells or others.

The present invention therefore ultimately makes it possible to respond to a problem wider than that initially considered.

The invention is not limited to the embodiments described above, and extends to all the embodiments covered by the claims.

In particular, as mentioned above, the invention also extends to any interconnection between string interconnecting strips 12.

Moreover, to decrease the mechanical stresses during temperature cycles, the interconnector 10 can further comprises a relaxation loop. This loop makes it possible to absorb the differences in coefficient of thermal expansion of different materials and the significant temperature differences.

1. An interconnector for at least one solar cell string forming a photovoltaic module, the interconnector comprising:
at least one cell interconnecting strip partially extending over a cell of the string, the cell being located at the end of the string, each cell interconnecting strip extending beyond said cell through an end, and
at least one string interconnecting strip,
wherein each from among said at least one interconnecting strip and said at least one string interconnecting strip extends in a main direction over a thickness measured in a direction perpendicular to a plane wherein the solar cell string mainly extends, and
wherein a section in a plane perpendicular to said main direction of an element taken from among said at least one cell interconnecting strip and said at least one string interconnecting strip has:
a substantially constant surface, and
a variable shape along the main direction at least between a first zone of a first thickness and a second zone of a second thickness, the second thickness of the second zone being strictly less than the first thickness of the first zone and the second thickness of the second zone being strictly less than 50 μm.

2. The interconnector according to the claim 1, wherein, with said element being a cell interconnecting strip, the cell interconnecting strip comprises the second zone located at the end and extends beyond the cell located at the end of the string.

3. The interconnector according to claim 1, wherein, with said element being a string interconnecting strip, the cell interconnecting strip comprises one second zone per cell interconnecting strip without a second zone, even per cell interconnecting strip, each second zone of the string interconnecting strip being preferably distant from at least one other second zone of the string interconnecting strip by a distance substantially equal to a separation distance between cell interconnecting strips adjacent to one another, the latter being arranged substantially parallel to one another.

4. The interconnector according to claim 1, comprising at least two cell interconnecting strips, and wherein at least one of the ends of said two cell interconnecting strips, which extend beyond the cells located at the end of the strings, is interconnected to the other of the two ends by said at least one string interconnecting strip by being resistance welded at at least one second zone.

5. The interconnector according to claim 1, further comprising at least two cell interconnecting strips, and wherein at least one of the ends of said at least two cell interconnecting strips, which extend beyond the cells located at the end of the strings, is interconnected to the other of the two ends by said at least one string interconnecting strip by being resistance welded at two second zones superposed to one another, one belonging to one of said at least two cell interconnecting strip, the other to the string interconnecting strip.

6. The interconnector according to claim 1, wherein the first zone has a thickness greater than or equal to 70 μm, the thickness being measured perpendicularly to a plane wherein the solar cell string mainly extends.

7. The interconnector according to claim 1, wherein the part of each cell interconnecting strip which extends over the cell located at the end of the string is without the second zone.

8. The interconnector according to claim 1, wherein each second zone extends over:
a substantially flat surface entering into the plane where the solar cell string mainly extends, and/or
a surface area substantially equal to 1 mm² projecting over the plane where the solar cell string mainly extends.

9. The interconnector according to claim 1, wherein said element is copper-based, and comprises a surface tin-plating of a thickness substantially between 20 and 25 μm and/or of a pure Ag, SnAg, SnPgAg, or SnBiAg composition.

10. A interconnector according to claim 1, having no soldering or bonding.

11. A photovoltaic module comprising solar cells, and at least one interconnector according to claim 1.

12. The photovoltaic module according to claim 11, wherein said at least one interconnector makes an electric junction between at least two solar cell strings, according to a series or parallel configuration of said at least two strings, and/or wherein said at least one interconnector is configured to make an electric junction between at least one solar cell string and external electronics.

13. The photovoltaic module according to claim 1, further comprising two protective plates and an encapsulant, said at least one interconnector and said at least one solar cell string being encapsulated by the encapsulant sandwiched between the two protective plates, the latter being constituted of a glass base.

14. A method for assembling a photovoltaic module according to claim 11, comprising a step of resistance welding between said at least one cell interconnecting strip and said at least one string interconnecting strip at at least one second zone.

15. The assembly method according to claim 14, further comprising a step of stamping, in a mould comprising an imprint and a punch, of a cell interconnecting strip of constant section and of thickness equal to said first thickness, the imprint and the punch being configured to deform the end of the cell interconnecting strip by stressing the cell interconnecting strip to progressively be spread out transversally to a thickness so as to preserve the unchanged length of the cell interconnecting strip while progressively reducing the thickness until reaching said second thickness and form a second zone.
